(19) United States
(12) Patent Application Publication
(10) Pub. No.: US 2011/0084310 A1
(43) Pub. Date: Apr. 14, 2011

(54) METHOD FOR OBTAINING A STRUCTURED MATERIAL WITH THROUGH OPENINGS, IN PARTICULAR NITRIDES OF TYPE III SEMICONDUCTORS STRUCTURED ACCORDING TO PHOTONIC CRYSTAL PATTERNS

(75) Inventors: Sylvain David, Meylan (FR); Philippe Boucaud, Paris (FR); Fabrice Semond, Mougins Le Haut (FR)

(73) Assignee: Universite Paris-Sud, Orsay (FR)

(21) Appl. No.: 12/863,267

(22) PCT Filed: Jan. 19, 2009
(86) PCT No.: PCT/FR09/50071

§ 371 Date: Dec. 13, 2010

(30) Foreign Application Priority Data
Jan. 18, 2008 (FR) 0850335

(51) Int. Cl. H01L 21/20; H01L 29/20; B05C 11/00; C23F 1/08

(52) U.S. Cl. 257/200; 438/478; 118/75; 257/E21.09; 257/E29.089

(57) ABSTRACT

A method of manufacture of a optical, photonic or optoelectronic component, including a so-called photonic slab or membrane that is traversed, in at least one internal region and according to a predetermined pattern, by a plurality of through openings having a micrometric or sub-micrometric transverse dimension, the method having the following steps: structuring of the surface of a substrate by an etching that produces holes in the substrate according to the pattern; depositing at least one layer of the photonic material forming the slab or membrane, by anisotropic epitaxial growth on the structured surface of the substrate around the opening of the holes.

The present invention relates to a method for obtaining an element of very small dimensions in a light-conducting material, sometimes called a photonic crystal. Such an element is most often in the form of a slab or a membrane, which is structured according to a predetermined pattern of through openings having a micrometric or sub-micrometric transverse dimension. The invention also relates to components that include such a crystal, as well as a system for the manufacture of said crystal or component.

These photonic crystals are used for example for making optical components in the broad sense, which are often called photonic when they have very small dimensions and/or optoelectronic when they comprise a part that functions electrically or electronically. Examples are light sources such as light-emitting diodes (LEDs) or lasers. These slabs or membranes can also be used for making passive or active components, such as photodetectors or modulators, for example for components for telecommunication by means of optical signals.

The nitride compounds of group III semiconductors are semiconducting materials with a wide forbidden band permitting the emission of light in the visible and ultraviolet regions of the spectrum. Their so-called “intra-band” emission can also be used for emission in the infrared. They have particularly good radiant efficiency. These compounds comprise for example gallium nitride (GaN), aluminium nitride (AlN) and indium nitride (InN). These materials are therefore of considerable interest for obtaining emitting components in optics and optoelectronics such as light-emitting diodes and lasers for the UV-visible region of the spectrum. The performance of these components can be optimized by structuring the emitting material. Structuring offers better control of the emitted light.

One method of utilizing these properties consists of making microcavities therein with a high quality factor, i.e. for which the lifetime of an electromagnetic mode in its cavity is high. These high quality factors are useful in particular in the case of light-emitting devices dedicated to information processing or transport. These microcavities promote coupling of the emitted light with the resonating optical element in order to benefit from certain physical effects such as the Purcell effect. This effect increases the level of spontaneous emission and reduces the emission threshold of microlasers and nanolasers.

These microcavities can be arranged in various patterns, and in particular so as to obtain periodical modulation of the dielectric constant of the material obtained, thus forming a “photonic crystal” around the microcavity. These photonic crystals are produced conventionally by etching holes in dielectric materials of high refractive index such as semiconductors. The required dimensions for these holes are of the order of about a hundred nanometres for the diameter, and from one to several hundred nanometres for their depth and their spacing.

The use of photonic crystals is beneficial since their photonic forbidden band offers better confinement of light. Such structures permit opening of the forbidden band, i.e. of a spectral range in which there are no optical modes. Therefore light cannot be propagated in structures with photonic crystals. By generating defects in these periodical structures, localized optical modes are obtained in the photonic crystal cavities that can be adjusted in the spectral range of the photonic forbidden band.

These photonic structures are two-dimensional photonic crystals combined with vertical variation of the refractive index. Generally they are effective for a single polarization. Arrays of holes etched in a high-index material promote the existence of a photonic forbidden band in transverse electric (“TE”) polarization, i.e. the configuration in which the electric field is perpendicular to the axis of the holes. Such structures imply geometries that respect the symmetries of the electromagnetic fields.

In order to dissociate the two polarizations, it is necessary for the structure to have vertical mirror symmetry relative to the horizontal mid-plane of the layer in which the two-dimensional photonic crystals are structured. That is, the upper structure replicates the bottom portion of the structure.

Concretely, such structures require in particular the observance of two conditions:
on the one hand that the patterns etched are vertical;
on the other hand that they are structured on the full thickness of the light-guiding layer, i.e. passing through the entire layer in which the two-dimensional photonic crystal is structured.

A known method for making such structures consists of making arrays of holes by anisotropic etching in a nitride material. Now, the etching of deep, regular holes presents certain difficulties for obtaining good geometric characteristics, the more so if the depth etched is large relative to the transverse dimensions.

This is even truer of certain materials whose chemical behaviour offers few possibilities for etching, for example nitrides and in particular aluminium nitride.

For such materials, the only types of etching available are in general types of etching based on reactive plasma (reactive ion etching, RIE). Now, these methods of reactive ion etching, for example for nitride compounds that are group III semiconductors, require heavy ion bombardment and at present do not permit vertical etching of micrometric or sub-micrometric patterns in sufficient thicknesses, i.e. of the order of about a hundred nanometres, and/or with satisfactory quality. It is found that the flanks are inclined at least 5 degrees relative to the axis of the holes, which limits the possibilities and performance, for example for said photonic crystals and their resonant microcavities and nanocavities.

Moreover, it is very interesting to have coexisting patterns with different shapes and characteristic dimensions, in order to produce components of the microcavity type with a high quality factor or transitional components such as refractive optical guide / photonic crystal guide adapters. Now, it is known that the rate of etching depends on the width of the patterns, for example the diameter of the holes. The simultaneous presence of patterns of different widths leads to non-uniform levels or depths of etching. Thus, in the case of patterns with very non-uniform sizes, the holes may not reach the substrate or their verticality may vary depending on the width of the etched patterns, which in each case introduces a vertical asymmetry and therefore optical losses.

Thus, with these techniques it is not possible to produce structures having different widths of patterns or different shapes. The width of the etched patterns has a considerable influence on this ion bombardment and therefore the rate of etching of these patterns. Therefore it is not possible in the case of variable geometry to have uniform depths of etching.

Finally, since these types of etching are particularly slow and require significant ion bombardment, there is low selectivity of etching, i.e. the ratio of the rate of etching of the material to the parasitic etching of the masks. In the case of patterns of small width, it may not be possible to etch the full thickness of the material vertically, or it may be limited by the need to use an excessive mask thickness.

Other methods consist of using local vertical epitaxial growth, i.e. through openings in a layer previously structured and serving as a mask, such as a silicon oxide or nitride. The patterns are determined by techniques of micro- and nano-lithography, then etched for example by a plasma or wet etching process. Growth then takes place in the openings of said mask.

If growth takes place by an MBE process (molecular beam epitaxy), the presence of the mask walls influences the verticality of the deposits by shadowing effects. For growth obtained by CVD processes (chemical vapour deposition), growth is characterized by selective deposition between the materials of the substrate and mask. Accordingly, the mask walls also influence the epitaxial growth and therefore the verticality of the patterns obtained. This is reflected in unintentional chamfering of the patterns grown epitaxially. This problem is more critical when, in structures with photonic crystals, the thickness of the layer grown epitaxially is of the order of magnitude of the width of the patterns.

Certain methods exist, such as those described in documents WO 2007/081381 or US 2003/0213428, for producing structuring of a comparable order of magnitude, often called nanowires or nanoislands.

These methods mainly consist of producing holes of a shape that is not very restrictive in a substrate, for growing the material facing the interior of these holes. These holes are filled by growth of a very selective type, such as the MOCVD process.

This type of production does not provide the shapes, nor often the qualities, for example geometric, that are required in many cases for making photonic crystals of the slab type with useful performance. For example, for this it would be necessary to connect up the nanowires obtained, which in particular is highly complex and poses a problem of geometric quality and of reliability. Moreover, the filling of the spaces makes the vertical profiles of the nanowires obtained very dependent on the surface condition of the holes, and subject to poor performance with respect to regularity and geometric conformity.

A purpose of the invention is to overcome the drawbacks of the prior art. In particular, an aim is to produce a material having through openings of different widths, over a larger thickness, and that have a geometry that is more symmetrical and more regular. Another purpose is to permit arbitrary selection of the position and of the shapes and dimensions of these openings.

Thus, the invention aims to provide the manufacture of components of the photonic or optoelectronic type that have better performance, with more varied characteristics, and/or more simply and economically.

The invention also aims to obtain these characteristics that are simpler to apply, in particular in existing industrial installations.

Although the present description essentially presents examples of structuring of materials based on nitrides of type III semiconductors, one objective of the invention is also to permit such structuring in other types of materials for dimensions of a similar order of magnitude.

The present invention proposes a method of production of structured layers of the photonic crystal type obtained through localized epitaxy induced by structuring the substrate. This method applies more particularly to materials of the nitride type of group III semiconductors, as it is very difficult to apply the usual methods of manufacture of photonic crystals with these materials.

A substrate, for example made of silicon, is structured deeply using known methods of micro- and nanotechnology: in particular optical or electronic lithography and reactive plasma etching.

The resin is then removed from the surface of the substrate so that it is exposed during growth. A layer of nitride of type III semiconductor (AlN, GaN, etc.) is deposited by epitaxy, localized on the remaining portion on the surface of the structured substrate. This layer thus forms a slab or membrane having structuring identical to the surface of the substrate.

Thus, the invention proposes a method for making an optical, photonic or optoelectronic component comprising a so-called photonic slab or membrane (20, 306, 406, 506). This photonic slab or membrane is traversed, in at least one internal region and according to a predetermined pattern, by a plurality of through openings (307, 407, 507) having a micrometric or sub-micrometric transverse dimension. This method comprises the following steps:
structuring the surface of a substrate by an etching which produces holes in said substrate according to said pattern;
depositing at least one layer of the photonic material forming the slab or membrane, by anisotropic epitaxial growth on the structured surface of said substrate around the opening of the holes forming this pattern. That is, said growth is localized on the remaining portions of the substrate surface. Typically, this growth takes place in a direction roughly perpendicular to the surface of the substrate.

More particularly, the through openings have walls defining a longitudinal profile that is approximately rectilinear and perpendicular to the mid-plane of the photonic slab or membrane.

This growth of the photonic slab or membrane, anisotropic and vertical relative to the substrate surface, permits direct transfer of the two-dimensional geometry of the patterns of the substrate in the layer thus grown epitaxially. It avoids direct etching, in particular for nitrides. This growth makes it possible to obtain complex patterns of good quality, which cannot be obtained by the standard techniques for the manufacture of photonic crystals.

The production of holes and photonic crystals without etching thus makes it possible to obtain geometries of better quality. Because ion bombardment is not used, it is also possible to obtain walls having a surface of better quality with reduced roughness.

Typically, the method can further comprise a subsequent step of ablation or separation of the substrate from the slab or membrane, on all or part of its surface.

For certain applications in photonics and optoelectronics, the substrate previously structured can simply be etched under the layer grown epitaxially, in order to release the latter and convert it into a membrane structure that remains bound to the substrate in certain places, for example on its perimeter. This method can be used for making emitting components such as light-emitting diodes and lasers that are effective in the spectral range of UV, visible and infrared radiation.

In particular, this step of ablation or separation of the substrate can comprise at least one operation of etching, under the membrane or slab obtained by selective chemical or selective photo-electrochemical attack, possibly by passing liquid or gaseous elements through the through openings obtained.

In the case of silicon, ablation of the substrate can be carried out by chemical etching that is selective relative to the layer grown epitaxially (for example the nitride of a group III element) in various ways. It can be carried out for example by wet etching based on KOH (potassium hydroxide), or a mixture of nitric, acetic (or water) and hydrofluoric acids, etc. It can also be carried out for example by isotropic plasma etching using fluorinated gases.

Although more difficult to apply, the photo-electrochemical etching can also be used for this ablation or separation for certain substrate materials that are more difficult to etch, for example silicon carbide.

The dimensional characteristics of the array can be adapted according to the desired wavelength. Thus, in the case of ultraviolet radiation, the structuring can typically comprise arrays with periods of 140 nm and hole diameters of 100 nm and etched to a depth in the range from one to several times the diameter of the etched holes. In the case of infrared radiation, the dimensions of the arrays will typically be of the order of one to several tens of microns.

According to the invention, the through openings of the structured device obtained are determined by the previous structuring of the substrate, and form an array that can comprise at least two openings having transverse dimensions different from one another.

According to the invention, the array can thus be constituted by holes of different sizes without being subject to the same difficulties as with the direct plasma etching of nitrides, as known from the prior art.

More particularly, the invention proposes producing a thickness of deposited photonic material greater than the transverse dimension of at least one through opening, for example its diameter, thus producing, for this through opening, an aspect ratio greater than 1.

According to a particular feature of the invention, at least one through opening can have a transverse dimension less than or equal to 1000 or 800 nm, typically less than 500 nm, or even less than 200 nm and for example up to about 80 nm.

Moreover, the invention also makes it possible to produce openings with large dimensions, for example several microns, as well as an arbitrary combination of openings the dimensions of which can vary over this entire range.

The array thus etched in the silicon substrate can in particular be arranged with a view to producing resonant microcavities and nanocavities or guiding structures.

Preferably, single-crystal silicon is used, with orientation according to the <111> direction, but the method can also use the other crystal directions <100> and <110>, or even directions not corresponding to the standard directions of the crystal lattice.

However, depending on the requirements of the application, the substrate that has to be structured beforehand can also be constituted by other materials, for example silicon and/or germanium alloy, doped silicon, a substrate of the SOI (silicon-on-insulator) type, or GaAs, SiC, AlN, ZnO, diamond, sapphire.

The silicon substrate is structured beforehand using processes from micro- and nano-technology.

During the growth step, the walls of the holes that structure the silicon substrate may be covered with a fine layer of growth material, for example aluminium nitride. This deposit is likely to interfere with the subsequent under-etching of the silicon during the step of ablation or separation. This covering of the walls of holes is carried out to a depth which is of the order of the width of the holes.

According to the invention, the step of structuring of the substrate preferably comprises etching of holes with dimensions that are larger in their depth than in the plane of said substrate. This deeper etching of the substrate thus makes it possible to keep a free surface of silicon at the bottom of the holes, which facilitates the under-etching used for the ablation or separation.

The invention is particularly advantageous for obtaining a structured slab or membrane in a compound based mainly on nitride of a type III semiconductor.

The material grown epitaxially can preferably be AlN but can also be GaN, or a homogeneous mixture of materials of type AlₓGa_{y}In_{1-x-y}N (with 0≦x+y≦1), either homogeneous or in different layers.

This production technique can also apply to materials of the gallium phosphide (GaP) type and any compound of the same type.

In the same context, the invention also proposes an optical, photonic or optoelectronic component, comprising said photonic crystal, or a slab or a membrane obtained by said method.

In the same context, the invention also proposes a system for the manufacture of said slab or membrane or a photonic crystal or an optical component, comprising means arranged for applying said method.

By permitting arbitrary selection of the position and shape, as well as of the width of the through openings and the thickness obtained, the invention makes it possible to improve the performance and the quality of the components. The invention also permits a wider choice in terms of spectral emission and power of the photonic-crystal components obtained, and to have greater flexibility in the adjustment of their properties.

By producing through openings of good quality to a considerable depth in the slab or membrane obtained, the invention makes it possible to obtain patterns with a high quality factor, i.e. a high depth/width ratio of the holes.

The invention can also make manufacture easier and simpler, for example by avoiding the etching of certain difficult materials such as nitrides. In fact, a large part of the operations used by the method according to the invention relates to the methods of manufacture of silicon dies, which are the processes best understood at present.

It makes it possible to produce patterns with openings with “vertical” flanks for producing photonic crystals for which verticality is a major aspect for obtaining photonic crystals for resonant structures with a high quality factor.

This invention can be integrated in the design of photonic or optoelectronic components using semiconducting materials based on nitrides of group III compounds, for example such as low-threshold microlasers or nanolasers, visible or UV or infrared light-emitting diodes with enhanced extraction efficiency, single-photon sources with cavity quantum boxes.

This technology offers many degrees of freedom and accepts geometries that are not accessible by direct plasma etching according to the prior art.

The industrial applications cover a wide spectrum in which optoelectronic devices occupy an important place. These components will typically relate to light sources for general lighting, signalling, screens (of computers, telephones, etc.), but also laser diodes operating in the blue for recording data and detectors and light-emitting diodes covering the visible and the ultraviolet spectrum and light emitters in the infrared.

Other features and advantages of the invention will become apparent on examination of the detailed description of an embodiment which is in no way limitative, and the attached drawings in which:

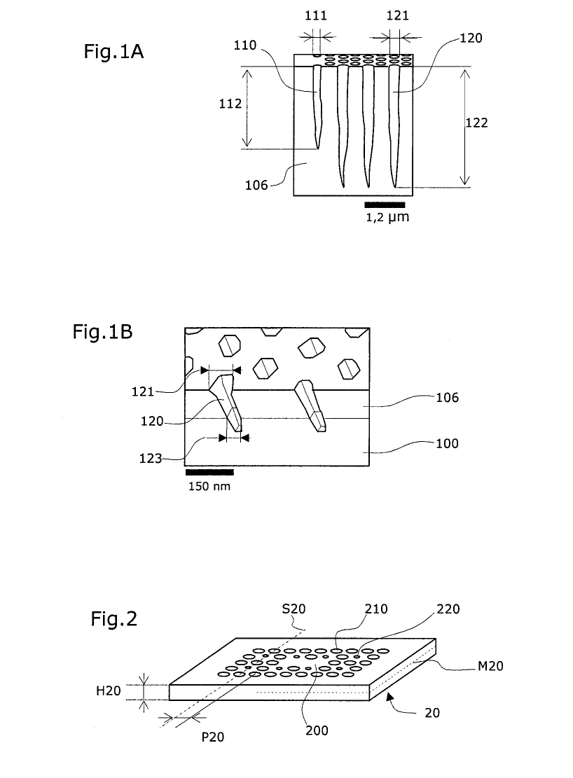

FIGS. 1A and B are perspective drawings to scale from photographs of two sections of photonic crystals made by etching according to the prior art;

FIG. 2 is a diagrammatic view in perspective of a slab obtained according to the invention, which has through openings according to an irregular pattern and can be used for making a photonic crystal or a photonic-crystal component;

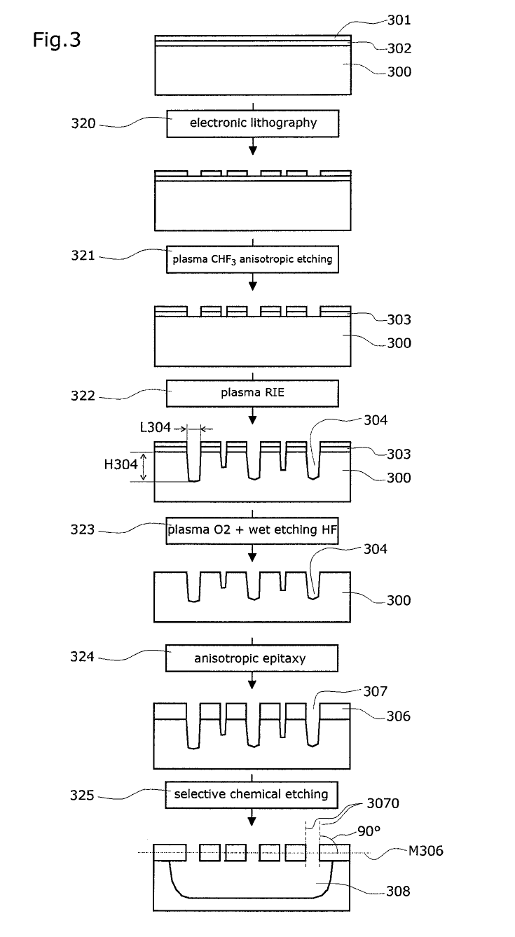

FIG. 3 is a diagrammatic illustration of the production of a membrane on a substrate according to a first embodiment of the invention, with an intermediate masking layer;

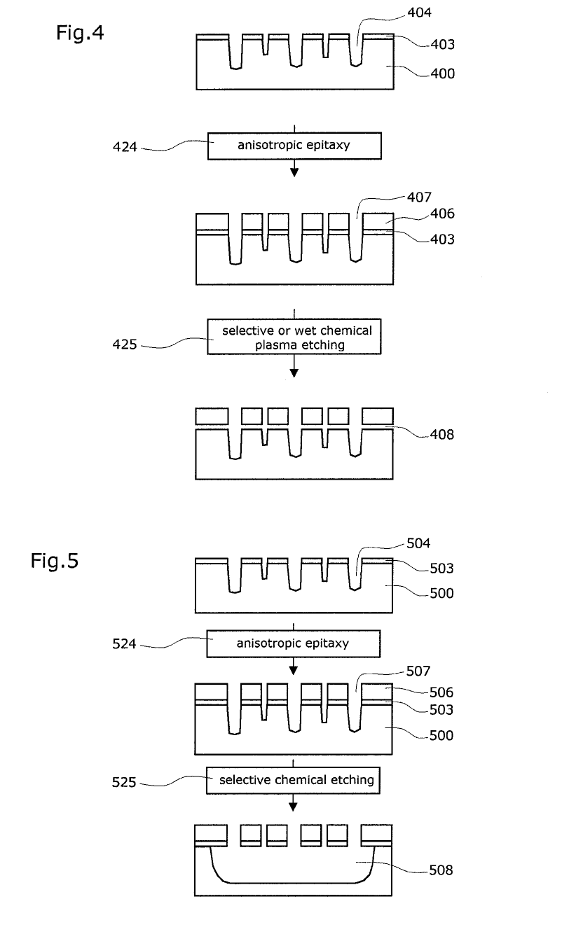

FIG. 4 is a diagrammatic illustration of the production of a slab according to a second embodiment of the invention, with a sacrificial layer on the substrate;

FIG. 5 is a diagrammatic illustration of the production of a membrane according to a third embodiment of the invention, with a tuning layer on the substrate;

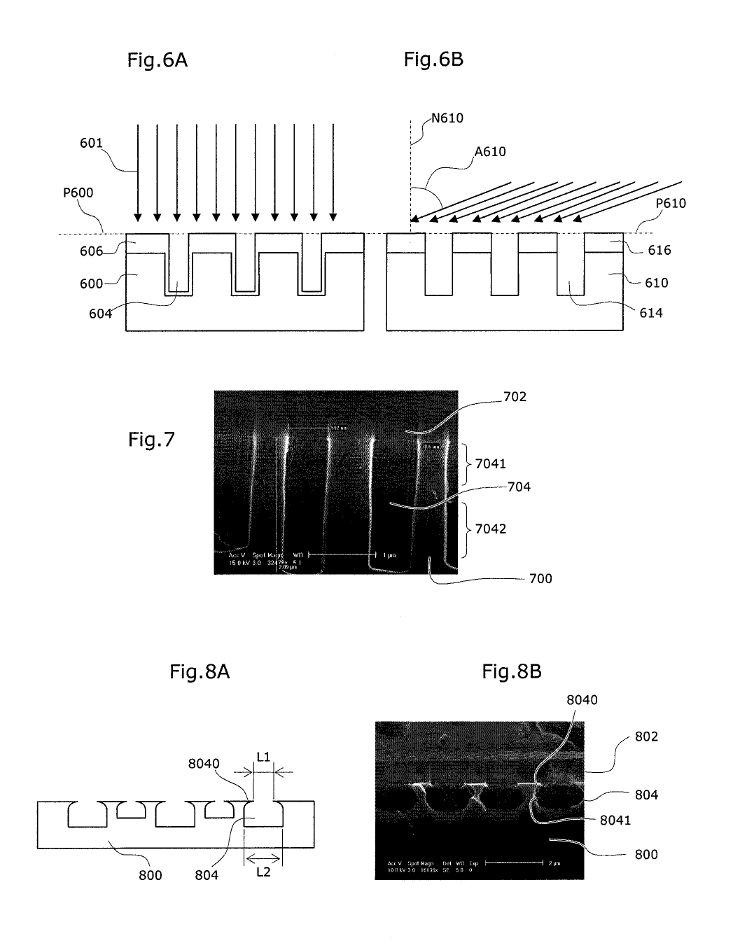

FIGS. 6A and B are diagrammatic illustrations of anisotropic growth according to two optional variants with different directions of incidence;

FIG. 7 is a scanning electron micrograph showing a perspective view of a section of a silicon substrate structured by an “unswitched” deep etching process;

FIGS. 8A and B show a diagrammatic representation and a scanning electron micrograph of a section of a structured silicon substrate in an optional variant with subjacent etching of the silicon relative to the upper interface of the slab;

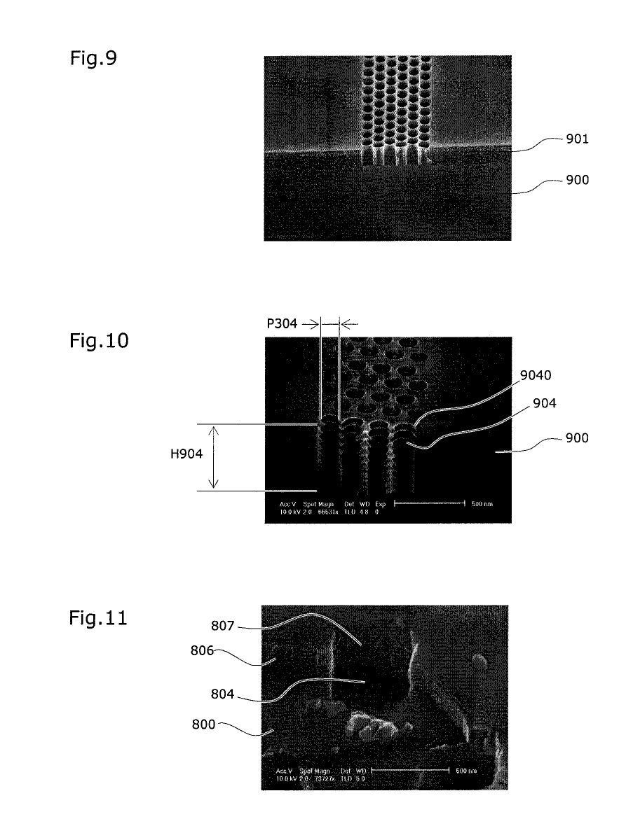

FIG. 9 and FIG. 10 are scanning electron micrographs showing a perspective view of a section of a lithographic resin mask for structuring the substrate, and respectively a silicon substrate structured with the aid of this resin mask by a so-called “switched” process of deep etching;

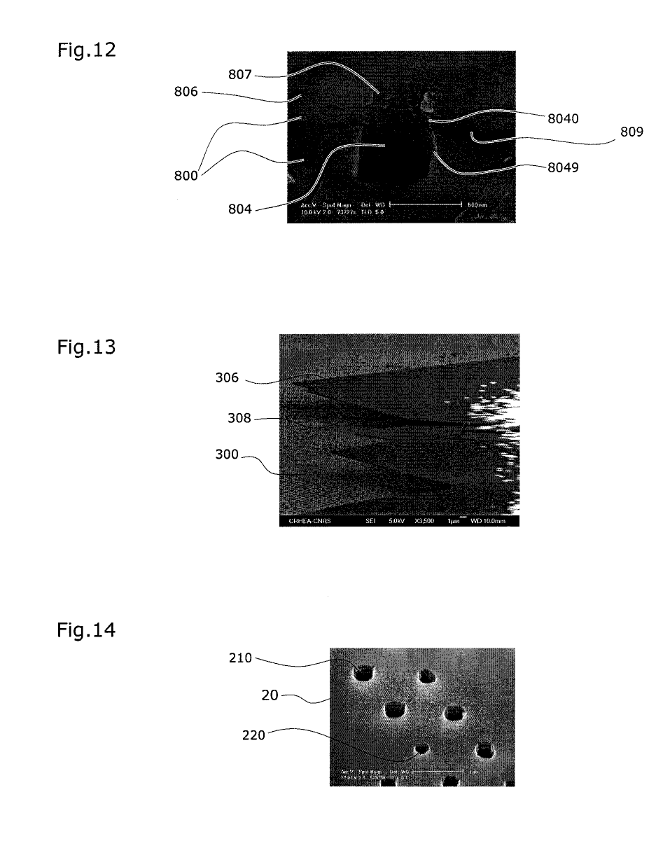

FIG. 11 and FIG. 12 are scanning electron micrographs showing a perspective view of cleaved specimens comprising a layer of nitride grown epitaxially on a silicon substrate;

FIG. 13 is a scanning electron micrograph showing a membrane grown epitaxially on a silicon substrate and released by under-etching;

FIG. 14 is a scanning electron micrograph showing a photonic layer grown epitaxially, which has patterns of various sizes, produced according to the invention.

Unless stated specifically, the diagrams are not shown to scale.

### ILLUSTRATIONS OF THE PRIOR ART

FIG. 1A is a drawing made to scale from a scanning electron micrograph of a cleaved section of a photonic crystal obtained according to the prior art, by plasma etching in a III-V semiconductor.

The rate of etching depends on the width of the etched patterns. As can be seen in the crystal section 106, two holes 110 and 120 with different diameters 111 and 121 therefore have very different depths of etching 112 and 122. Moreover, their vertical profile is very irregular and narrows considerably in the end portion, which means that the largest thickness usable for producing a photonic crystal would be limited to the portion without narrowing of the narrowest hole 110.

FIG. 1B is a drawing made to scale from a scanning electron micrograph of a cleaved section of a photonic crystal obtained according to the prior art, etched with chlorine plasma in a layer 106 of gallium nitride (GaN) carried by a substrate 100 of silicon carbide (SiC).

In this figure we can see the variation in width of the holes 120 as a function of the depth, between their top part 121 and their bottom part 123 in crystal 106, which constitutes a drawback of the prior art.

### DETAILED DESCRIPTION OF AN EMBODIMENT OF THE INVENTION

The type of substrate must be selected on the one hand in relation to compatibility with the materials to be grown epitaxially, and on the other hand in relation to the types of selective etching available for the subsequent ablation or separation from the substrate. Silicon substrates (111) are good candidates. They can be etched selectively relative to III-N compounds by simple wet etching, such as etching with KOH (potassium hydroxide), or with mixtures of acids (for example: nitric, acetic and hydrofluoric), etc.

In this method, epitaxial growth of the materials is by localized growth induced by the structuring of the substrate in order to transfer, to the deposited layers, the two-dimensional geometry of the patterns previously etched in the substrate. This growth can, for example, be obtained during deposition of AlN, or of AlGaN.

This property of anisotropic growth normal to the surface, therefore localized outside of the holes in the substrate, is obtained by a small diffusion path of the chemical species deposited on the surface of the layer grown epitaxially and a technique of epitaxial growth with strong directionality of the flows of molecules. In this method, the differences in depth of the patterns etched previously in the substrates have no effect on the vertical structuring of the layers grown epitaxially. Thus, this method also makes it possible to produce more complex patterns, for example photonic structures with several (and/or different) holes per unit cell of the lattice.

FIG. 2 shows a photonic crystal in the form of a slab 20 obtained according to the invention, with a thickness H2O of the order of about a hundred nanometres. This slab is structured with through openings 210, 220 in a pattern forming an array with a period P20 with different sizes of holes, and having an unperforated zone in a region 200 of this array. The through openings have a longitudinal profile that is rectilinear and perpendicular relative to the slab 20, and more precisely relative to the mid-plane M20 of said slab.

FIG. 3 illustrates the steps in production of this slab according to a preferred embodiment, seen in vertical section (perpendicular to the plane of the slab) along line S20 shown as a dot-and-dash line in FIG. 2.

Substrate 300 is constituted by bulk silicon with crystal orientation of type (111), which is the most compatible with the wurtzite structure (hexagonal lattice).

The step of structuring of substrate 300 comprises at least one operation of lithography, for example of the electronic type. A layer 301 that is photosensitive or suitable for electronic lithography makes it possible to obtain a first structuring on the substrate. In the case of structuring with sufficiently large dimensions, it is also possible to use optical lithography.

Optionally, the step of structuring of the substrate comprises at least one operation of anisotropic etching 321 of an intermediate layer (for example of SiO₂ or Si₃N₄) serving as a mask for etching said substrate.

According to an option shown in this figure, an intermediate layer 302 (or a set of layers) is intercalated between the photosensitive layer 301 and the initial substrate 300 to form a supplementary mask in order to provide sufficient selectivity for etching the substrate. This intermediate layer 302 can typically be a material based on silicon oxide or nitride.

Anisotropic etching 321 of the intermediate layer (or layers) 302 in a mask 303 is carried out for example by a method of plasma etching such as plasma CHF₃, through the openings in layer 301 that are revealed by lithography.

The step of structuring of the substrate comprises at least one etching operation 322, for example by reactive ion plasma.

Substrate 300 is etched 322 by a process of anisotropic reactive ion plasma etching, different from the process of etching 321 of the intermediate mask 303. This etching process 322 is selected to provide deep etching 304 in order to produce patterns having high aspect ratios, i.e. a ratio of depth to width greater than one, or even greater than two or greater than four. This deep etching process can typically be an etching process of the “switched” type, i.e. alternating etching and passivation, for example the so-called “Bosch process”, the result of which is shown later in FIG. 10.

The holes 304 obtained in substrate 300 have transverse dimensions L304 and depth dimensions called longitudinal H304.

The layer of masking resin 301, as well as the intermediate masking layer 302, which are optional, are removed 323 from the substrate for example by plasma etching (e.g. plasma O₂) and/or in acid solution in order to free the upper surface of the silicon 300.

Anisotropic epitaxial growth 324 makes it possible to obtain a layer 306 of nitride of type III semiconductor, for example AlN or GaN or InN, possibly in several layers with different compositions, structured with patterns formed from through openings 307, according to the structuring of the substrate by the holes 304 previously etched in substrate 300.

In step 325, the substrate is etched to release the layer 306 grown epitaxially and make it into a membrane suspended above the space 308 freed in substrate 300. This etching is carried out for example in liquid or gaseous solution providing selective chemical etching through the openings 307 in the membrane 306 thus obtained.

Thus, the through openings 307 obtained have many walls 3070 defining a longitudinal rectilinear profile that is perpendicular relative to the slab 306, and more precisely relative to the mid-plane M306 of said slab.

### OTHER EMBODIMENTS

Other embodiments are presented in FIG. 4 and FIG. 5, which can be combined with each other or with the principal embodiment.

Thus, FIG. 4 shows certain steps, subsequent to the etching 322 of substrate 400, in the production of a slab 406 according to a second embodiment of the invention, which can be combined with other embodiments.

In this second embodiment, the method comprises the production of at least one intermediate layer 403, called sacrificial, between substrate 400 and the slab 406 or membrane.

This sacrificial layer can be produced by anisotropic epitaxy after the etching 322 of substrate 400 and before the deposition 424 of the photonic material 406. It can also be produced by known methods, before the etching 320 to 322 of substrate 400.

The slab or membrane 406 is grown epitaxially 424 on this sacrificial layer 403. Depending on the lattice matching of the sacrificial material 403 relative to that of the substrate 400, the thickness of the sacrificial layer will be varied in order to limit the dislocations in the material of the membrane 406.

This sacrificial layer 403 is then destroyed or degraded in the course of the step of ablation or separation 425 of this substrate.

This variant can be useful especially if the substrate is of a material that is difficult to etch for separation 425, for example a sacrificial layer of silicon on a silicon carbide substrate.

FIG. 5 shows certain steps, subsequent to the etching 322 of substrate 500, in the production of a membrane 506 according to a third embodiment of the invention, which can be combined with other embodiments.

In this third embodiment, the method comprises the production of at least one intermediate layer 503, called the tuning layer, between substrate 500 and the slab or membrane 506.

This sacrificial layer can be produced by anisotropic epitaxy after the etching 322 of substrate 500 and before deposition 524 of the photonic material 506. It can also be produced by known methods, before the etching 320 to 322 of the substrate 500.

This tuning layer 503 is in a different material from the substrate and is selected for its capacity to receive anisotropic epitaxial growth of better quality, for example by covering the silicon substrate with a layer of nitride or with some other layer promoting lattice matching between the material of substrate 500 and the epitaxially-grown layer 506 of nitride of group III semiconductor.

It should be noted that the sacrificial layer and the tuning layer can be combined as a single layer by selecting a material that fulfils both functions.

These two layers—sacrificial and tuning—can also be combined in one and the same embodiment, not shown here, and can be superposed in either order.

In the first and third embodiments shown here in FIG. 3 and FIG. 5, the substrate 300, 500 is etched 325, 525 only in a partial region 308, 508 relative to the material 306, 506 grown epitaxially. Once formed, this material thus remains suspended and can be called a membrane.

Alternately or combined in different regions of one and the same substrate wafer, substrate 400 can be etched on the entire surface of the material 406 grown epitaxially. As shown for example in FIG. 4, this material 406 will then be completely separated 425 from the substrate 400, and can then be called a slab.

In an alternative not shown here, the substrate can also be destroyed or degraded from its face opposite to the slab that has been formed, according to known techniques.

FIG. 6A and FIG. 6B show two possible variants, which can be combined with each other, for localized anisotropic growth 324, 424, 524 of the material of the crystal on the structured substrate.

In FIG. 6A, anisotropic growth takes place along a direction of supply 601 of material, typically by a process of molecular beam epitaxy (MBE), approximately normal to the plane P600 of the surface of substrate 600. As shown in the diagram, the growing material 606 may then also tend to accumulate on the vertical walls of the holes 604 in the substrate, which is detrimental to the verticality and symmetry of the openings in the slab or membrane obtained, and degrades the geometry by increasing the roughness of the walls.

FIG. 6B shows an advantageous variant offered by the invention. A direction of supply 611 is provided that is oblique or even glancing, for example at an angle A610 greater than 45° or even greater than 60° with respect to the normal N610 to the plane P610 of the surface of the substrate 610. This oblique or glancing direction can be achieved for example by modifying the geometry of the reactor to increase the angle between the normal to the substrate and the axis of the effusion cells. This variant offers a stronger shadowing effect during deposition, which causes little or no deposition on the flanks of the etched patterns in the substrates and at the bottom of the patterns.

FIG. 7 shows a substrate 700 structured with blind holes 704, with circular openings with a diameter of about 590 nm and a pattern pitch of about 1300 nm. The substrate 700 also carries the mask 702 of SiO₂ which served for producing this structuring. This photograph shows that the holes 704 in the structured substrate have a radius about 30 nm larger in the top part 7041 than in the bottom part 7042. Such a difference would be troublesome for a through opening that would be etched directly in a photonic crystal according to the prior art. According to the invention, such an imperfection in the etching of the holes in the substrate does not prevent the production of through openings with satisfactory geometry in the layer of nitride that will be grown epitaxially on this substrate.

FIG. 8A and FIG. 8B show an optional variant that can be combined with the other embodiments. These figures show, in section, a silicon substrate 800 structured with holes having a transverse dimension that is larger beneath the interface of the substrate than at the level of this interface itself.

FIG. 8A is a diagrammatic representation of the substrate after structuring. FIG. 8B is a photograph showing this same structured substrate still carrying the mask 302 of SiO₂ which was used for producing this structuring.

In this variant, the step of structuring 322 of the substrate comprises etching of holes 804 whose transverse dimensions L2 at depth are greater than their transverse dimensions L1 on the surface of said substrate 800. This difference produces a rim 8040 of reduced thickness in the form of a lip around the opening of the hole 804, and the walls 8041 situated below this lip 8040 are thus less likely to receive a deposit of nitride during subsequent growth of the photonic crystal on the substrate.

This difference in widths, when it is obtained by etching operations, is sometimes called “under-etching”, in the sense that it is etched underneath (at depth) rather than on the surface. These operations can for example combine anisotropic etching to make the hole, followed by isotropic etching to increase the dimensions of the hole beneath the surface.

FIG. 9 and FIG. 10 show, respectively, a resin mask 901, and the structured substrate 900 obtained using this mask by etching 322 according to the “switched” method called the “Bosch process”. Such a process is particularly indicated for obtaining good geometry of the holes 904, in particular in the case shown here where these holes 904 are of small dimensions, here about 140 nm in diameter L904 for a depth H904 of about 500 nm, and for a pattern pitch of about 180 nm. Moreover, as seen in the photograph, the characteristics of this switched method are entirely suitable for obtaining or amplifying a certain “under-etching”, i.e. wider etching below the surface of the substrate and forming a lip 9040 at the level of said surface.

FIG. 11 and FIG. 12 show, in perspective and according to two different sections, a layer of aluminium nitride grown epitaxially on a structured silicon substrate by conventional anisotropic etching and slightly “under-etched”. These photographs show the crystal after formation but before isotropic etching of the substrate 800. In FIG. 12, it can be seen in particular that the hole 804 in the substrate 800 has a smaller width at its opening than at depth, thus forming a lip 8040, which made it possible to limit the deposits of nitride on the silicon walls 8049. In FIG. 12, it should be noted that the portion of the silicon substrate near the surface only appears to be separated from the rest of the substrate by an optical effect creating an irregular shadow zone 809, which is due to the operation of sectional cutting, or cleavage, carried out subsequently to make the interior of the hole visible in the photograph.

FIG. 13 is a scanning electron micrograph showing a membrane grown epitaxially 306 on a silicon substrate 300 and released by under-etching 325 of an intermediate space 308.

FIG. 14 is a scanning electron micrograph showing a layer grown epitaxially that has patterns of different sizes. These patterns were transferred by the epitaxy step 324 from the patterns previously etched in the substrate 300. It can be seen that significant differences in size (in transverse dimensions), at least from single to double, are permissible according to the invention without this translating into a difference in depth of the through opening in the slab or membrane 20. In fact, this thickness is determined by the duration and rate of deposition. This method does not have limits a priori on the differences in size of through holes that can be obtained.

It should be noted that the specimen in FIG. 14 only constitutes a demonstration test with the aim of obtaining through openings 210 and 220 with different transverse dimensions on one and the same photonic crystal 20. The transverse shape of the through openings depends on that of the holes made for the previous structuring of the growth substrate. On this specimen, the regularity of this shape does not represent the best possibilities attainable by the method according to the invention.

Of course, the invention is not limited to the examples which have just been described and numerous adjustments can be made to these examples without exceeding the scope of the invention.

1. A method of manufacture of a optical, photonic or optoelectronic component, comprising a so-called photonic slab or membrane that is traversed, in at least one internal region and according to a predetermined pattern, by a plurality of through openings having a micrometric or sub-micrometric transverse dimension, said method comprising the following steps:
structuring of the surface of a substrate by an etching that produces holes in said substrate according to said pattern;
depositing at least one layer of the photonic material forming the slab or membrane, by anisotropic epitaxial growth on the structured surface of said substrate around the opening of said holes.

2. The method according to claim 1, characterized in that it further comprises a subsequent step of ablation or separation of the substrate from the slab or membrane, in at least one region.

3. The method according to claim 1, characterized in that the through openings have walls defining a longitudinal profile approximately rectilinear and perpendicular to the mid-plane of the photonic slab or membrane.

4. The method according to claim 1, characterized in that the through openings form an array comprising at least two openings having transverse dimensions different from one another.

5. The method according to claim 1, characterized in that the thickness of photonic material deposited, relative to the transverse dimensions of at least one through opening, produces an aspect ratio of at least one for said through opening.

6. The method according to claim 1, characterized in that at least one through opening has a transverse dimension less than or equal to 500 nm.

7. The method according to claim 1, characterized in that the structured slab or membrane is of a compound predominantly based on a nitride of a type III semiconductor.

8. The method according to claim 1, characterized in that the anisotropic growth step comprises at least one operation of growth by supply of molecules according to an incident direction making an angle of at least 45° with the normal to the surface of the substrate.

9. The method according to claim 1, characterized in that the substrate is in single-crystal silicon of <111> orientation.

10. The method according to claim 1, characterized in that it comprises the production of at least one intermediate layer, called tuning layer, between the substrate and the slab or membrane, said tuning layer being of a different material from the substrate and selected for its capacity to receive anisotropic epitaxial growth of good quality.

11. The method according to claim 1, characterized in that the step of structuring of the substrate comprises the etching of openings with larger dimensions in depth than in the surface plane of said substrate.

12. The method according to claim 1, characterized in that the step of structuring of the substrate comprises etching of openings whose transverse dimensions are smaller at the surface of said substrate than at depth.

13. The method according to claim 1, characterized in that the step of structuring of the substrate comprises at least one operation of etching by electronic or optical lithography of at least one layer serving as a mask for the etching of said substrate.

14. The method according to claim 1, characterized in that the step of ablation or separation of the substrate comprises at least one operation of etching, under the membrane or slab obtained, by selective chemical or selective photo-electrochemical attack.

15. The method according to claim 14, characterized in that the step of ablation or separation of the substrate comprises at least one passage of liquid or gaseous elements through the through openings obtained.

16. A component comprising at least one photonic slab or membrane obtained by the method according to claim 1.

17. A system for the manufacture of a slab or membrane or photonic crystal or an optical or optoelectronic component, characterized in that it comprises means arranged for applying a method according to claim 1.
